(19) United States
(12) Patent Application Publication
(10) Pub. No.: US 2013/0088839 A1
(43) Pub. Date: Apr. 11, 2013

(54) BOARD MODULE MANUFACTURING METHOD, BOARD MODULE, AND BOARD MODULE ASSEMBLY

(71) Applicant: FUJITSU LIMITED, Kawasaki-shi (JP)

(72) Inventors: Takatoyo YAMAKAMI, Nagano (JP); Takashi KUBOTA, Chikuma (JP); Kuniko ISHIKAWA, Nagano (JP); Masayuki KITAJIMA, Yokohama (JP)

(73) Assignee: FUJITSU LIMITED, Kawasaki-shi (JP)

(21) Appl. No.: 13/628,070

(22) Filed: Sep. 27, 2012

(30) Foreign Application Priority Data
Oct. 4, 2011 (JP) 2011-220403

(51) Int. Cl. H05K 3/00; B23K 31/02; H05K 7/06

(52) U.S. Cl. CPC H05K 3/00; H05K 7/06; B23K 31/02
USPC 361/728; 228/211; 228/176

(57) ABSTRACT

There is provided a method of manufacturing a board module which includes attaching a metal particle to a surface of a solder bump, which includes at least a tin component and is mounted on an electrode provided on a first surface of an electric part or a printed circuit board, the metal particle having a higher specific gravity and a higher melting point than the solder bump, making the first surface face up, heating the solder bump to a temperature equal to or higher than the melting point of the solder bump so that the metal particle precipitates in the solder bump, and forming an inter-metal compound layer, which has a higher melting point than a melting point of the solder bump, at an interface between the solder bump and the electrode by using the metal particle, which has precipitated, and the tin component of the solder bump.

### CROSS-REFERENCE TO RELATED APPLICATION

This application is based upon and claims the benefit of priority of the prior Japanese Patent Application No. 2011-220403, filed on Oct. 4, 2011, the entire contents of which are incorporated herein by reference.

### FIELD

The embodiments discussed herein are related to a board module manufacturing method, a board module, and a board module assembly.

### BACKGROUND

A board module includes an electronic part such as a chip size package (CSP) and a printed circuit board such as an interposer. On the board module, the electronic part and printed circuit board are bonded together by a bonding material such as solder. In a broad sense, a CSP formed by mounting a semiconductor chip on a package board is also a type of board module. The board module is formed by bonding electrodes mounted on the printed circuit board and electrodes mounted on the electronic part together. After these electrodes have been bonded together, spaces formed between the printed circuit board and the electronic part are usually filled with an under-fill material such as a synthetic resin. The under-fill material reinforces the bonding between the printed circuit board and the electronic part, for example.

The board module is mounted on a printed circuit board called a mother board or system board, this mounting is called secondary mounting. The board module mounted on the mother board in this way is called a board module assembly. In a process to place the board module on the mother board as the secondary mounting, reflow processing is carried out in which the board module and mother board are heated to the melting point of solder. As a result, bonded solder in the board module melts again. The bonding solder is solder with which the electrodes on the printed circuit board and the electrodes on the electronic part are bonded together.

FIGS. 15A and 15B illustrate an example of a board module. The board module 100 in FIG. 15A includes an electronic part 110 and a printed circuit board 120; electrodes 111 on the electronic part 110 and electrodes 121 on the printed circuit board 120 are electrically bonded together by using solder 130. With the board module 100, spaces formed between the electronic part 110 and the printed circuit board 120 are filled with an under-fill material 140 such as a synthetic resin. The under-fill material 140 reinforces the bonding between the electronic part 110 and the printed circuit board 120.

However, the board module 100 may include spaces 150 at an interface between the printed circuit board 120 and the under-fill material 140 and at an interface between the electronic part 110 and the under-fill material 140 due to voids formed or dust built up during the filling of the under-fill material 140.

In a process to manufacture a board module assembly by placing the board module 100 on a mother board as secondary mounting, for example, the solder 130, which electrically bonds the electrodes 111 and electrodes 121 together in the board module 100, melts again. The solder 130, which includes melted, flows into spaces 150 by capillary action, as illustrated in FIG. 15B. As a result, adjacent electrodes 111 on the electronic part 110 and adjacent electrodes 121 on the printed circuit board 120 are short-circuited by the solder 130, which includes flowed into the spaces 150, forming solder flashes.

FIGS. 16A and 16B illustrate an example of a process to manufacture a board module 100A. In FIG. 16A, a solder ball 130A, which is made of Sn—Ag—Cu (SAC) solder, is mounted in advance on each electrode 111A placed on the front surface of an electric part 110A. Electronic parts in which solder balls are mounted in advance are available in the recent market. A manufacturing apparatus (not illustrated) applies solder paste 131A, made of SAC solder, that includes copper particles 132 to electrodes 121A on a printed circuit board 120A.

The manufacturing apparatus then brings the surface of each solder ball 130A mounted on the electrode 111A on the electric part 110A into contact with the solder paste 131A applied to the relevant electrode 121A on the printed circuit board 120A. The manufacturing apparatus heats the electric part 110A and the printed circuit board 120A with the surface of the solder ball 130A brought into contact with the solder paste 131A. As a result, as illustrated in FIG. 16B, an inter-metal compound layer 160 having a higher melting point than the solder ball 130A is formed at an interface between the electrode 121A on the printed circuit board 120A and the solder ball 130A, the inter-metal compound layer 160 including the tin component of the solder ball 130A and the copper particles 132 of the solder paste 131A.

Even if the space 150 is formed near the electrode 121A on the printed circuit board 120A in the board module 100A and thereby the solder ball 130A melts again during the secondary mounting, for example, the inter-metal compound layer 160 near the electrode 121A does not melt because the inter-metal compound layer 160 has a higher melting point than the solder ball 130A. Accordingly, the inter-metal compound layer 160 may suppress the solder from flowing into the space 150 and may thereby suppress solder flashes from being formed on the electrode 121A.

Japanese Laid-open Patent Publication Nos. 2008-161881, 2009-224700, and 2001-358440 are examples of related art.

### SUMMARY

According to an aspect of the invention, a method of manufacturing a board module includes attaching a metal particle to a surface of a solder bump, which includes at least a tin component and is mounted on an electrode provided on a first surface of an electric part or a printed circuit board, the metal particle having a higher specific gravity than that of the solder bump and a higher melting point than that of the solder bump; making the first surface, on which the electrode is provided, face up; heating the solder bump to a temperature equal to or higher than the melting point of the solder bump to melt the solder bump so that the metal particle precipitates in the solder bump; and forming an inter-metal compound layer, which has a higher melting point than a melting point of the solder bump, at an interface between the solder bump and the electrode by using the metal particle, which has precipitated, and the tin component of the solder bump.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a board module in a first embodiment;

FIG. 2 is an enlarged view illustrating a cross section of the board module in the first embodiment;

FIGS. 3A to 3E illustrate is part of an example of a process to manufacture the board module in the first embodiment;

FIGS. 4A to 4D are a continuation of the example of the process to manufacture the board module in the first embodiment;

FIG. 5 illustrates an example of the board module in the first embodiment;

FIGS. 6A to 6C illustrate an example of a process to manufacture a board module assembly in the first embodiment;

FIG. 7 is an enlarged view illustrating a cross section of the board module in a second embodiment;

FIGS. 8A to 8E illustrate part of an example of a process to manufacture the board module in the second embodiment;

FIGS. 9A to 9D are a continuation of the example of the process to manufacture the board module in the second embodiment;

FIGS. 10A to 10E illustrate part of an example of a process to manufacture the board module in a third embodiment;

FIGS. 11A to 11D are a continuation of the example of the process to manufacture the board module in the third embodiment;

FIGS. 12A to 12C illustrate an example of an experiment in which the third embodiment was used;

FIGS. 13A to 13E illustrate exemplary metal composition analysis results of a solder ball and an inter-metal compound layer on one electrode mounted on a test element group (TEG) board;

FIG. 14 illustrates an example of a silver-plated copper particle;

FIGS. 15A and 15B illustrate an example of a board module;

FIGS. 16A and 16B illustrate an example of a process to manufacture a board module; and

FIGS. 17A to 17B illustrate an example of a problem with the board module in FIGS. 16A and 16B.

### DESCRIPTION OF EMBODIMENTS

FIGS. 17A and 17B illustrate an example of a problem with the board module 100A. The inter-metal compound layer 160 is formed near the interface between the 121A on the printed circuit board 120A and the solder ball 130A, as illustrated in FIG. 17A. Since the inter-metal compound layer 160 has a high melting point, it does not melt during secondary mounting, suppressing the solder from flowing into the space 150 near the electrode 121A on the printed circuit board 120A.

With the board module 100A, however, there is no inter-metal compound layer 160 at the interface between the electrode 111A on the electric part 110A and the solder ball 130A. Therefore, the solder near the interface melts during the secondary mounting, and the solder that has melted again flows into the space 150 near the electrode 111A on the electric part 110A as illustrated in FIG. 17B. The solder that has flows into the space 150 forms solder flashes, which short-circuit adjacent electrodes 111A on the electric part 110A. That is, solder flashes are likely to be formed near the electrodes on the side on which solder balls are mounted in advance.

Embodiments of a board module manufacturing method, a board module, and a board module assembly disclosed in this application will be described below in detail with reference to the drawings. The disclosed technology is not limited by these embodiments.

### First Embodiment

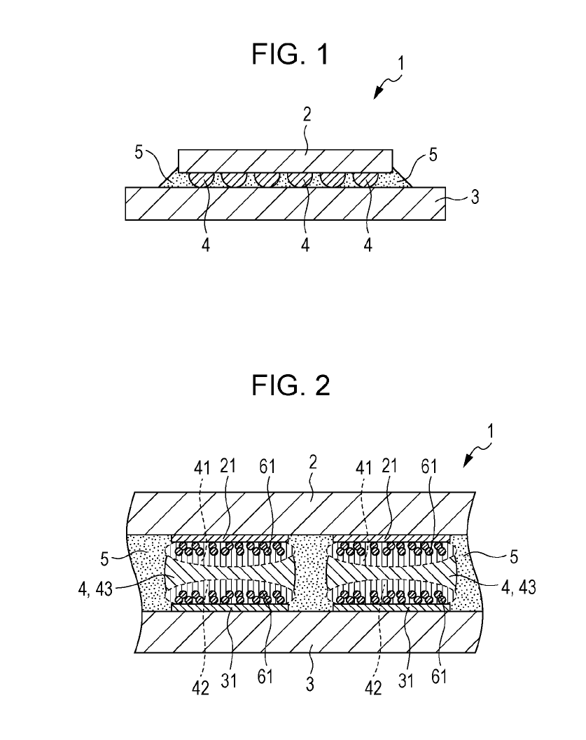

FIG. 1 illustrates an example of a board module in a first embodiment, and FIG. 2 is an enlarged view illustrating a cross section of the board module in the first embodiment. The board module 1 in FIGS. 1 and 2 includes an electronic part 2 such as a chip size package (CSP), a printed circuit board 3 such as an interposer, and solder balls 4, made of Sn—Ag—Cu (SAC) solder, which electrically bond the electronic part 2 and printed circuit board 3 together. The board module 1 further includes an under-fill material 5 with which spaces between the electronic part 2 and the printed circuit board 3 are filled. The electronic part 2 includes first electrodes 21 on its front surface, one solder ball 4 being mounted on each first electrode 21. If the SAC solder ball 4 is made of Sn-3Ag-0.5Cu solder, for example, its specific gravity is 7.4047 ((7.3×0.965)+(10.52×0.03)+(8.92×0.005)).

The printed circuit board 3 includes second electrodes 31 on its front surface. The solder ball 4 mounted on each first electrode 21 on the electronic part 2 is brought into contact with the relevant second electrode 31 on the printed circuit board 3, and the first electrode 21 and second electrode 31 are electrically bonded together by using the solder ball 4 through a manufacturing process described later. When the first electrodes 21 and second electrodes 31 are electrically bonded together by using the solder balls 4, the board module 1 is formed.

At the interface between the first electrode 21 and the solder ball 4 in the board module 1, there is a first inter-metal compound layer 41 formed with copper particles 61, which will be described later, and the tin component of the solder ball 4, the first inter-metal compound layer 41 being a Cu—Sn layer, for example. The melting point (about 260° C., for example) of the first inter-metal compound layer 41 is higher than the melting point (about 230° C., for example) of the solder ball 4. At the interface between the second electrode 31 and the solder ball 4 in the board module 1, there is a second inter-metal compound layer 42 formed with the copper particles 61 and the tin component of the solder ball 4, the second inter-metal compound layer 42 being a Cu—Sn layer, for example. The melting point (about 260° C., for example) of the second inter-metal compound layer 42 is higher than the melting point of the solder ball 4.

There is also an intermediate layer 43 formed between the first inter-metal compound layer 41 and the second inter-metal compound layer 42 by using the solder ball 4 disposed between the first inter-metal compound layer 41 and the second inter-metal compound layer 42. Since the intermediate layer 43 is a constituent of the solder ball 4, the intermediate layer 43 has a lower melting point than the first inter-metal compound layer 41 and second inter-metal compound layer 42, but is superior in solder wettability, electrical conductivity, and physical strength to solder including a large amount of copper.

With the board module 1, each space between the electronic part 2 and the printed circuit board 3 is filled with the under-fill material 5 such as a synthetic resin to reinforce the bonding between the electronic part 2 and the printed circuit board 3. Furthermore, the board module 1 assures insulation between adjacent first electrodes 21 and between adjacent second electrodes 31 with the under-fill material 5. The under-fill material 5, which includes a thermosetting resin and an inorganic filler, is supplied to each space between the electronic part 2 and the printed circuit board 3 by using a dispenser (not illustrated).

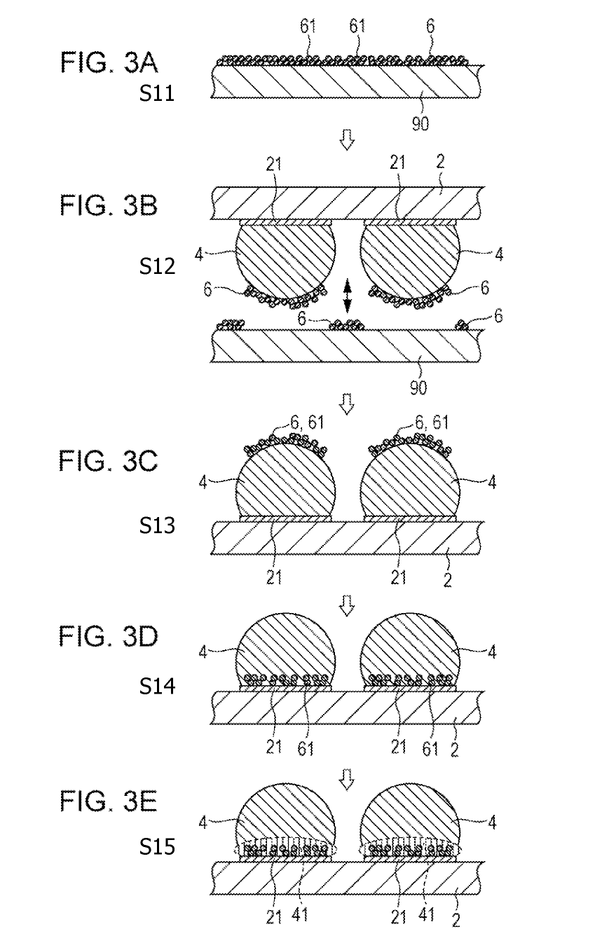

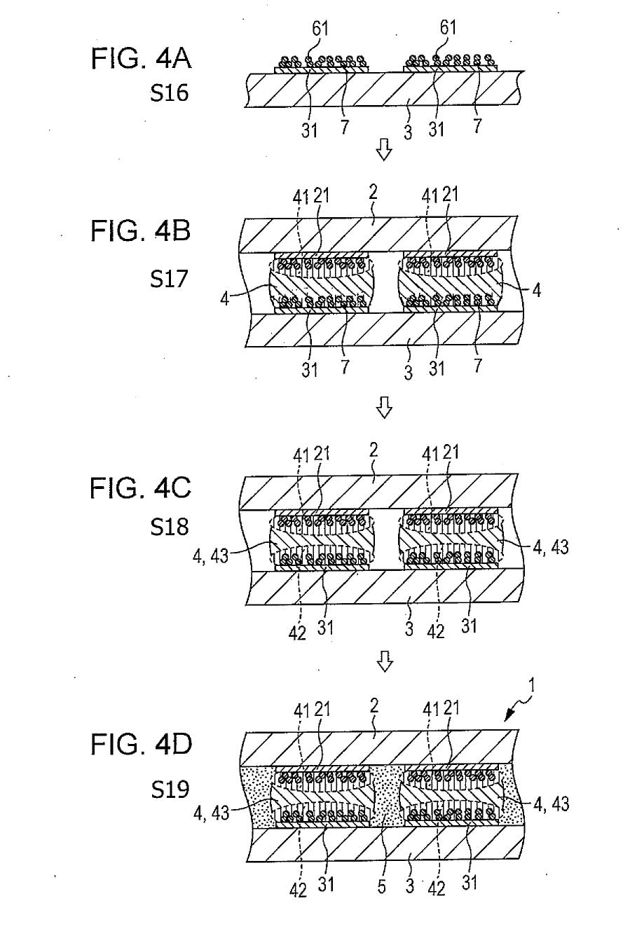

Next, a process to manufacturing the board module 1 in the first embodiment will be described. FIGS. 3A to 3E and FIGS. 4A to 4D illustrate an example of the process to manufacture the board module 1 in the first embodiment. The solder ball 4 and solder pastes 6 and 7 are used, where the solder ball 4 is made of Sn-3Ag-0.5Cu solder, and solder pastes 6 and 7, which will be described later, are made of SAC solder including the copper particles 61 and a flux.

A manufacturing apparatus (not illustrated) squeezes the solder paste 6, which includes the copper particles 61 and a flux, onto a transfer stage 90 (step S11). The manufacturing apparatus places the electronic part 2 on which the solder balls 4 made of SAC solder have been mounted on the transfer stage 90 so that the front surface of the electronic part 2 faces down and its rear surface faces up. The manufacturing apparatus then transfers the solder paste 6 from the transfer stage 90 to the surfaces of the solder balls 4 (step S12). The manufacturing apparatus inverts the electronic part 2 so that the solder paste 6 transferred to the surfaces of the solder balls 4 faces up, that is, the rear surface of the electronic part 2 faces down and its front surface faces up (step S13). At this time, the solder paste 6 including the copper particles 61 remains attached to the surface of the solder ball 4 mounted on each first electrode 21 on the electronic part 2. Since the specific gravity of the copper particle 61 is 8.92 and that of the solder ball 4 made of SAC solder is 7.4047, so the specific gravity of the copper particle 61 is greater than that of the solder ball 4. The diameter of the copper particle 61 is in the range from about 20 μm to about 50 μm, for example. The melting point of the solder ball 4 is about 230° C. and that of the copper particle 61 is about 1,000° C., so the melting point of the copper particle 61 is higher than that of the solder ball 4.

The manufacturing apparatus performs first heat processing on the inverted electronic part 2 to melt the solder balls 4 mounted on the electronic part 2 (step S14). In the first heat processing, the electronic part 2 is heated for about three minutes at the melting point of the solder ball 4, that is, at a temperature of, for example, about 230° C. As the solder ball 4 melts, the copper particles 61 in the solder paste 6 applied to the surface of the solder ball 4 precipitate under their own weight at an interface between the interior of the melted solder ball 4 and the first electrode 21.

After the copper particles 61 have precipitated at the interface between the interior of the solder ball 4 and the first electrode 21, the manufacturing apparatus performs second heat processing on the electronic part 2 to form the first inter-metal compound layer 41 at the interface between the interior of the solder ball 4 and the first electrode 21 (step S15). In the second heat processing, the electronic part 2 is heated for about four hours at a temperature of about 150° C. to form the first inter-metal compound layer 41, made of Cu—Sn, having a high melting point with the copper particles 61 and tin component.

The manufacturing apparatus applies the solder paste 7 including the copper particles 61 to each second electrode 31 disposed on the front surface of the printed circuit board 3 (step S16). The solder paste 7 is made of SAC solder including the copper particles 61. The manufacturing apparatus performs third heat processing on the printed circuit board 3 and electronic part 2 with the solder ball 4 mounted on each first electrode 21 being brought into contact with the solder paste 7 applied to the relevant second electrode 31 (step S17). In the third heat processing, the electronic part 2 and printed circuit board 3 are heated for about three minutes at the melting points of the solder ball 4 and solder paste 7, that is, at a temperature of, for example, about 230° C.

After having performed the third heat processing on the electronic part 2 and printed circuit board 3, the manufacturing apparatus performs fourth heat processing on the electronic part 2 and printed circuit board 3 to form the second inter-metal compound layer 42 at an interface between the interior of the solder ball 4 and the second electrode 31 (step S18). In the fourth heat processing, the electronic part 2 and printed circuit board 3 are heated for about four hours at a temperature of, for example, about 150° C. to form the second inter-metal compound layer 42, made of Cu—Sn, having a high melting point with the copper particles 61 and tin component. As a result, in the board module 1, the intermediate layer 43 having a low melting point is formed between the first inter-metal compound layer 41 and the second inter-metal compound layer 42 by using the solder ball 4 disposed between the first inter-metal compound layer 41 and the second inter-metal compound layer 42.

After having formed the second inter-metal compound layer 42 at the interface between the interior of the solder ball 4 and the second electrode 31, the manufacturing apparatus uses a dispenser (not illustrated) to fill each space between the electronic part 2 and the printed circuit board 3 with the under-fill material 5 (step S19). This completes the manufacturing of the board module 1, by the manufacturing apparatus, in which the electronic part 2 and printed circuit board 3 are bonded together.

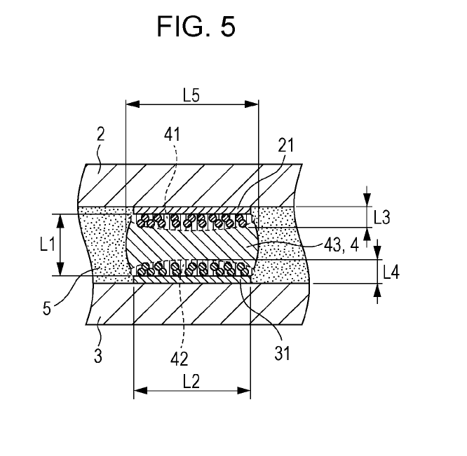

FIG. 5 illustrates an example of the board module 1 in the first embodiment. In FIG. 5, the distance L1 between the first electrode 21 and the second electrode 31 is 0.25 mm, for example; the horizontal length L2 of the first electrode 21 and second electrode 31 is 0.25 mm, for example; the thickness L3 of the first inter-metal compound layer 41 from the front surface of the electronic part 2 is 0.03 mm or more, for example; the thickness L4 of the second inter-metal compound layer 42 from the front surface of the printed circuit board 3 is 0.03 mm or more, for example. The thicknesses L3 and L4 are not smaller than the thickness of the spaces that are formed at the interface between the electronic part 2 and the under-fill material 5 and at the interface between the printed circuit board 3 and the under-fill material 5 when the under-fill material 5 is supplied. The horizontal length L5 of the intermediate layer 43 formed by the solder ball 4 disposed between the first inter-metal compound layer 41 and the second inter-metal compound layer 42 is 0.26 mm, for example.

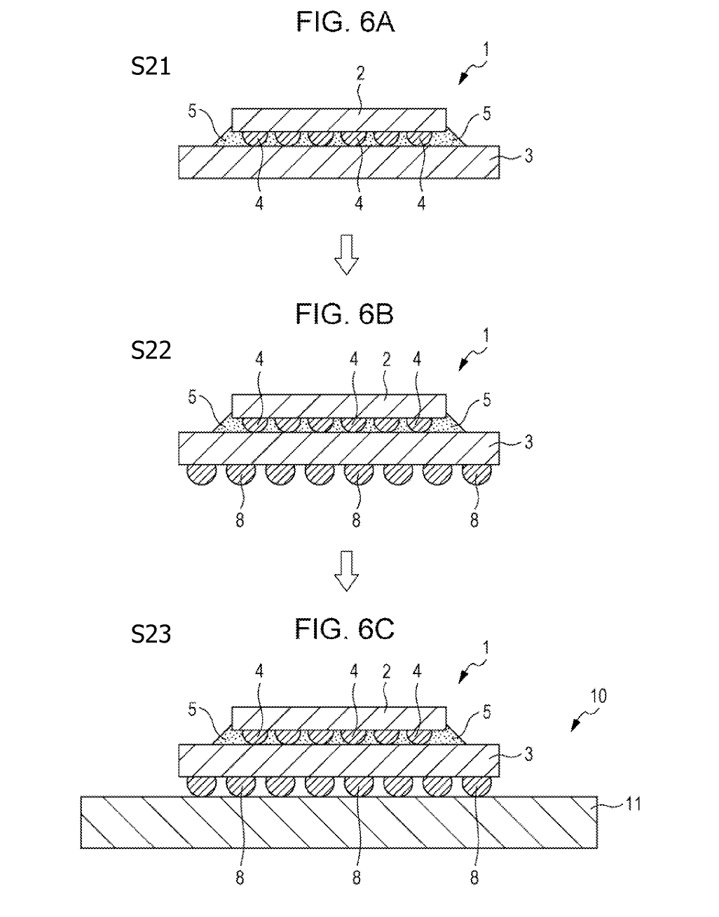

Next, a process to manufacture a board module assembly will be described. FIGS. 6A to 6C illustrate an example of a process to manufacture a board module assembly 10 in the first embodiment. The board module assembly 10 is formed by placing the board module 1 on a mother board 11 as the secondary mounting and electrically bonding the board module 1 and mother board 11 together. The manufacturing apparatus prepares the completed board module 1 (step S21) and performs fifth heat processing on the completed board module 1 to mount solder balls 8 made of SAC solder on the rear surface of the printed circuit board 3 in the board module 1 (step S22). In the fifth heat processing, the board module 1 is heated for about three minutes at the melting point of the solder ball 8, that is, at a temperature of, for example, about 230° C. in the case when SAC solder is used. Accordingly, when the fifth heat processing is performed on the board module 1, the solder ball 4, which electrically bonds the first electrode 21 and second electrode 31 together, also melts again. Since the first inter-metal compound layer 41 and second inter-metal compound layer 42 (see FIG. 2) have a high melting point, however, it is possible to suppress solder flashes from being formed near the first electrode 21 and second electrode 31.

The manufacturing apparatus further performs sixth heat processing on the board module 1 and mother board 11 with the solder balls 8 mounted on the rear surface of the board module 1 being brought into contact with the front surface of the mother board 11 (step S23). As a result, the solder balls 8 between het board module 1 and he mother board 11 melt in the sixth heat processing, by which the board module 1 and the mother board 11 are bonded together, manufacturing the board module assembly 10. In the sixth heat processing, the board module 1 and mother board 11 are heated for about three minutes at the melting point of the solder ball 4, that is, at a temperature of, for example, about 230° C. in the case when SAC solder is used. Accordingly, when the sixth heat processing is performed on the board module 1, the solder ball 4, which electrically bonds the first electrode 21 and second electrode 31 together, melts again. Since the first inter-metal compound layer 41 and second inter-metal compound layer 42 (see FIG. 2) have a high melting point, however, it is possible to suppress solder flashes from being formed near the first electrode 21 and second electrode 31.

In the manufacturing method in the first embodiment, the solder balls 4 made of SAC solder are placed on the first electrodes 21 of the electronic part 2, the solder paste 6 including the copper particles 61 is applied to the surfaces of the solder balls 4, and the electronic part 2 is placed upside down. In the manufacturing method, the solder ball 4 and solder paste 6 are melted and the copper particles 61 precipitate under their own weight at the interface between the interior of the melted solder ball 4 and the first electrode 21. In the manufacturing method, the tin component in the solder ball 4 and the copper particles 61 that have precipitated at the interface between the interior of the solder ball 4 and the first electrode 21 form the first inter-metal compound layer 41 having a high melting point at the interface between the interior of the solder ball 4 and the first electrode 21. In the manufacturing method, the solder paste 7 including the copper particles 61 is applied to each second electrode 31 on the printed circuit board 3, and the solder ball 4 mounted on the relevant first electrode 21 is placed on the second electrode 31. In the manufacturing method, the solder ball 4 and solder paste 7 are melted, and the tin component and the copper particles 61 of the solder paste 7 form the second inter-metal compound layer 42 having a high melting point at the interface between the interior of the solder ball 4 and the second electrode 31. In the manufacturing method, the board module 1 is manufactured by filling each space between the electronic part 2 and the printed circuit board 3 with the under-fill material 5. As a result, in the manufacturing method in the first embodiment, not only the second inter-metal compound layer 42 is formed on the same side as the second electrode 31, but also the first inter-metal compound layer 41 having a high melting point may be easily formed on the same side as the first electrode 21, on which the solder ball 4 has been mounted in advance.

In addition, the board module 1 includes the first inter-metal compound layer 41 formed at the interface between the interior of the solder ball 4 and the first electrode 21 and also includes the second inter-metal compound layer 42 formed at the interface between the interior of the solder ball 4 and the second electrode 31. When the board module 1 is placed on the mother board 11 as the secondary mounting, the solder ball 4, which bonds the first electrode 21 and second electrode 31 together in the board module 1, melts again. Even when the solder ball 4 melts again, the first inter-metal compound layer 41 and second inter-metal compound layer 42 do not melt because they have a high melting point, suppressing solder flashes from being formed on the first electrode 21 and second electrode 31.

The board module 1 also includes the intermediate layer 43, which is formed with the low-melting point component of the solder ball 4, between the first inter-metal compound layer 41 and the second inter-metal compound layer 42. Accordingly, although the intermediate layer 43 has a lower melting point than the first inter-metal compound layer 41 and second inter-metal compound layer 42, the intermediate layer 43 is superior in solder wettability, electrical conductivity, and physical strength to solder including a large amount of copper.

In the manufacturing method in the first embodiment, the tin component and the copper particles 61 that precipitated at the interface between the interior of the solder ball 4 and the first electrode 21 have been heated for about four hours at a temperature of, for example, about 150° C. to form the first inter-metal compound layer 41, made of Cu—Sn, at the interface between the interior of the solder ball 4 and the first electrode 21. As a result, the first inter-metal compound layer 41 having a higher melting point than the solder ball 4 may be formed at the interface between the interior of the solder ball 4 and the first electrode 21.

Although, in the first embodiment, SAC solder balls have been used as the solder balls 4 mounted on the first electrode 21 on the electronic part 2 in the board module 1, Sn—Bi solder balls may be used. An embodiment in which Sn—Bi solder balls are used will be described below as a second embodiment.

### Second Embodiment

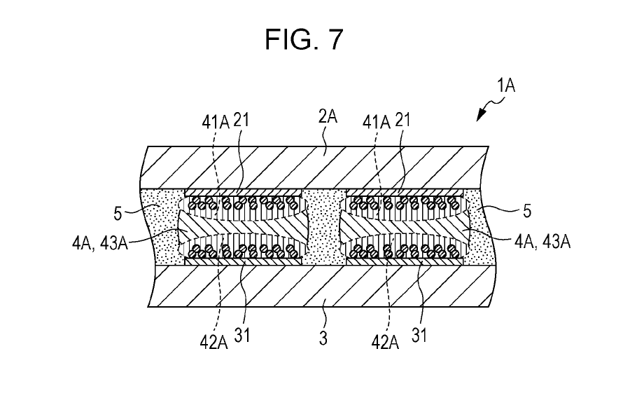

FIG. 7 illustrates a cross section of a board module 1A in a second embodiment. The same elements as in the board module 1 in FIG. 1 are denoted by the same reference numerals and repeated descriptions will be omitted. The board module 1A in FIG. 7 includes solder balls 4A made of Sn—Bi solder on the first electrode 21 disposed on the front surface of an electronic part 2A. If the Sn—Bi solder ball 4A is made of Sn-58Bi solder, for example, its specific gravity is 8.75 ((7.3×0.42)+(9.8×0.58)).

The solder ball 4A mounted on each first electrode 21 on the electronic part 2A is brought into contact with the relevant second electrode 31 on the printed circuit board 3, and the first electrode 21 and second electrode 31 are electrically bonded together by using the solder ball 4A through a manufacturing process described later, forming the board module 1.

At the interface between the first electrode 21 and the solder ball 4A in the board module 1A, there is a first inter-metal compound layer 41A formed with the copper particles 61 and the tin component of the solder ball 4A, the first inter-metal compound layer 41A being a Cu—Sn layer, for example. The melting point (about 260° C., for example) of the first inter-metal compound layer 41A is higher than the melting point (about 140° C., for example) of the solder ball 4A. At the interface between the second electrode 31 and the solder ball 4A in the board module 1A, there is a second inter-metal compound layer 42A formed with the copper particles 61 and the tin component of the solder ball 4A, the second inter-metal compound layer 42A being a Cu—Sn layer, for example. The melting point (about 260° C., for example) of the second inter-metal compound layer 42A is higher than the melting point (about 140° C., for example) of the solder ball 4A.

There is also an intermediate layer 43A formed between the first inter-metal compound layer 41A and the second inter-metal compound layer 42A by using the solder ball 4A disposed between the first inter-metal compound layer 41A and the second inter-metal compound layer 42A. Since the intermediate layer 43A is a constituent of the solder ball 4A, the intermediate layer 43A has a lower melting point than the first inter-metal compound layer 41A and second inter-metal compound layer 42A, but is superior in solder wettability, electrical conductivity, and physical strength to solder including a large amount of copper.

With the board module 1A, each space between the electronic part 2A and the printed circuit board 3 is filled with the under-fill material 5 to reinforce the bonding between the electronic part 2A and the printed circuit board 3. Furthermore, the board module 1A assures insulation between adjacent first electrodes 21 and between adjacent second electrodes 31 with the under-fill material 5.

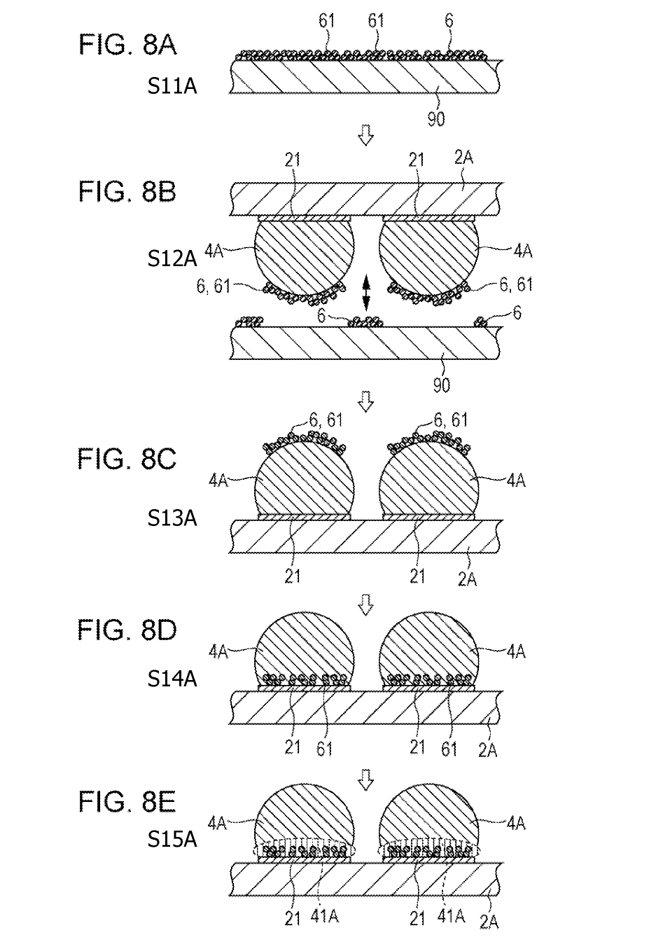

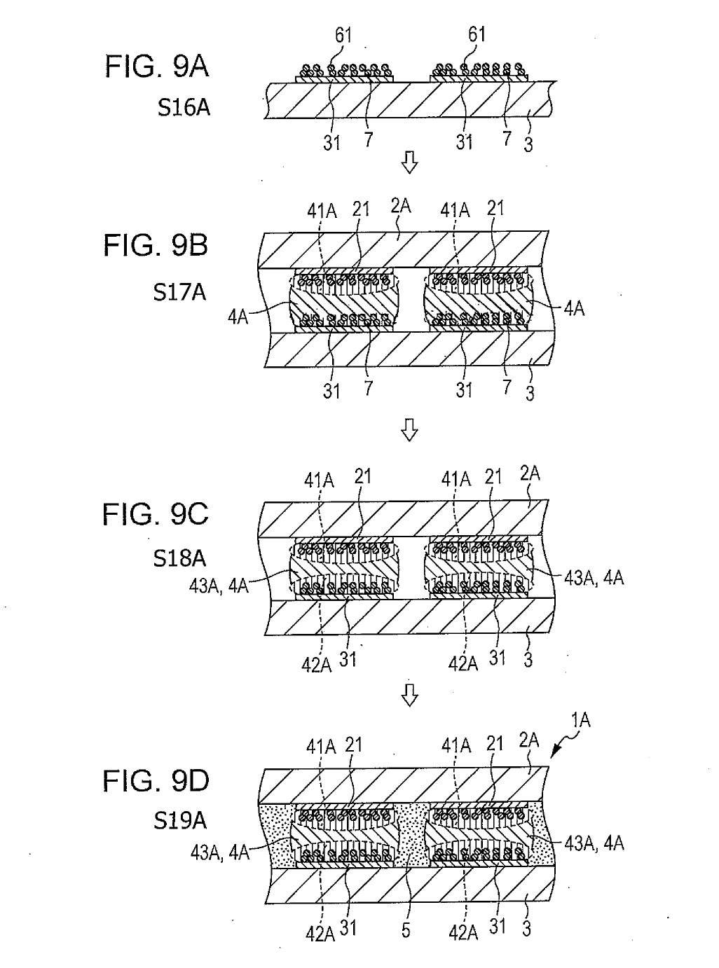

Next, a process to manufacturing the board module 1A in the second embodiment will be described. FIGS. 8A to 8E and FIGS. 9A to 9D illustrate an example of the process to manufacture the board module 1A in the second embodiment. The solder ball 4A is made of Sn-58Bi solder, and the solder pastes 6 and 7, which will be described later, are made of solder including the copper particles 61 and a flux.

A manufacturing apparatus (not illustrated) squeezes the solder paste 6, which includes the copper particles 61 and a flux, onto the transfer stage 90 (step S11A). The manufacturing apparatus places the electronic part 2A on which the solder balls 4A made of Sn—Bi solder have been mounted on the transfer stage 90 so that the front surface of the electronic part 2A faces down and its rear surface faces up. The manufacturing apparatus then transfers the solder paste 6 from the transfer stage 90 to the surfaces of the solder balls 4A mounted on the electronic part 2A (step S12A). The manufacturing apparatus inverts the electronic part 2A so that the solder paste 6 transferred to the surfaces of the solder balls 4A faces up, that is, the rear surface of the electronic part 2A faces down and its front surface faces up (step S13A). At this time, the solder paste 6 including the copper particles 61 remains applied to the surface of the solder ball 4A mounted on each first electrode 21 on the electronic part 2A. Since the specific gravity of the copper particle 61 is 8.92 and that of the solder ball 4A made of Sn—Bi solder is 8.75, so the specific gravity of the copper particle 61 is greater than that of the solder ball 4A. The diameter of the copper particle 61 is in the range from about 20 μm to about 50 μm, for example. The melting point of the solder ball 4A is about 140° C. and that of the copper particle 61 is about 1,000° C., so the melting point of the copper particle 61 is higher than that of the solder ball 4A.

The manufacturing apparatus performs first heat processing on the inverted electronic part 2A to melt the solder balls 4A mounted on the electronic part 2A (step S14A). In the first heat processing, the electronic part 2A is heated for about three minutes at the melting point of the solder ball 4A, that is, at a temperature of, for example, about 140° C. As the solder ball 4A melts, the copper particles 61 in the solder paste 6 applied to the surface of the solder ball 4A precipitate under their own weight at an interface between the interior of the melted solder ball 4A and the first electrode 21.

After the copper particles 61 have precipitated at the interface between the interior of the solder ball 4A and the first electrode 21, the manufacturing apparatus performs second heat processing on the electronic part 2A to form the first inter-metal compound layer 41A at the interface between the interior of the solder ball 4A and the first electrode 21 (step S15A). In the second heat processing, the electronic part 2A is heated for about four hours at a temperature of about 120° C. to form the first inter-metal compound layer 41A made of Cu—Sn, having a high melting point with the copper particles 61 and tin component.

The manufacturing apparatus applies the solder paste 7 including the copper particles 61 to each second electrode 31 disposed on the front surface of the printed circuit board 3 (step S16A). The solder paste 7 is made of solder including the copper particles 61 and a flux. The manufacturing apparatus performs third heat processing on the printed circuit board 3 and electronic part 2A with the solder ball 4A mounted on each first electrode 21 being brought into contact with the solder paste 7 applied to the relevant second electrode 31 (step S17A). In the third heat processing, the electronic part 2A and printed circuit board 3 are heated for about three minutes at the melting point of the solder ball 4A, that is, at a temperature of, for example, about 140° C.

After having performed the third heat processing on the electronic part 2A and printed circuit board 3, the manufacturing apparatus performs fourth heat processing on the electronic part 2A and printed circuit board 3 to form the second inter-metal compound layer 42A at an interface between the interior of the solder ball 4A and the second electrode 31 (step S18A). In the fourth heat processing, the electronic part 2A and printed circuit board 3 are heated for about four hours at a temperature of, for example, about 120° C. to form the second inter-metal compound layer 42A, made of Cu—Sn, having a high melting point with the copper particles 61 and tin component. Furthermore, in the board module 1A, the intermediate layer 43A is formed between the first inter-metal compound layer 41A and the second inter-metal compound layer 42A by using the solder ball 4A disposed between the first inter-metal compound layer 41A and the second inter-metal compound layer 42A.

After having formed the second inter-metal compound layer 42A at the interface between the interior of the solder ball 4A and the second electrode 31, the manufacturing apparatus uses a dispenser (not illustrated) to fill each space between the electronic part 2A and the printed circuit board 3 with the under-fill material 5 (step S19A). This completes the manufacturing of the board module 1A, by the manufacturing apparatus, in which the electronic part 2A and printed circuit board 3 are bonded together.

When the solder balls 8 are mounted on the rear surface of the completed board module 1A or the board module 1A is placed on the mother board 11 as the secondary mounting by using the solder balls 8, each solder ball 4A, which bonds the first electrode 21 and second electrode 31 together in the board module 1A, also melts again. Since the first inter-metal compound layer 41A and second inter-metal compound layer 42A (see FIG. 7) have a high melting point, however, it is possible to suppress solder flashes from being formed near the first electrode 21 and second electrode 31.

In the manufacturing method in the second embodiment, not only the second inter-metal compound layer 42A is formed on the same side as the second electrode 31, but also the first inter-metal compound layer 41A having a high melting point may be easily formed on the same side as the first electrode 21, on which the solder ball 4A has been mounted in advance.

In addition, the board module 1A includes the first inter-metal compound layer 41A formed at the interface between the interior of the solder ball 4A and the first electrode 21 and also includes the second inter-metal compound layer 42A formed at the interface between the interior of the solder ball 4A and the second electrode 31. When the board module 1A is placed on the mother board 11 as the secondary mounting, each solder ball 4A, which bonds the first electrode 21 and second electrode 31 together in the board module 1A, melts again. Even when the solder ball 4A melts again, the first inter-metal compound layer 41A and second inter-metal compound layer 42A do not melt because they have a high melting point, suppressing solder flashes from being formed on the first electrode 21 and second electrode 31.

The board module 1A also includes the intermediate layer 43A, which is formed with the low-melting point component of the solder ball 4A, between the first inter-metal compound layer 41A and the second inter-metal compound layer 42A. Accordingly, although the intermediate layer 43A has a lower melting point than the first inter-metal compound layer 41A and second inter-metal compound layer 42A, the intermediate layer 43A is superior in solder wettability, electrical conductivity, and physical strength to solder including a large amount of copper.

In the manufacturing method in the second embodiment, the tin component and the copper particles 61 that precipitated at the interface between the interior of the solder ball 4A and the first electrode 21 have been heated for about four hours at a temperature of, for example, about 120° C. to form the first inter-metal compound layer 41A, made of Cu—Sn, at the interface between the interior of the solder ball 4A and the first electrode 21. As a result, the first inter-metal compound layer 41A having a higher melting point than the solder ball 4A may be formed at the interface between the interior of the solder ball 4A and the first electrode 21.

Although, in the first embodiment, solder including the copper particles 61 and a flux has been used as the solder paste 6 applied to the surface of the solder ball 4 and the solder paste 7 applied to the second electrode 31, an Sn—Bi solder paste including the copper particles 61 may be used. An embodiment in which an Sn—Bi paste is used will be described below as a third embodiment.

### Third Embodiment

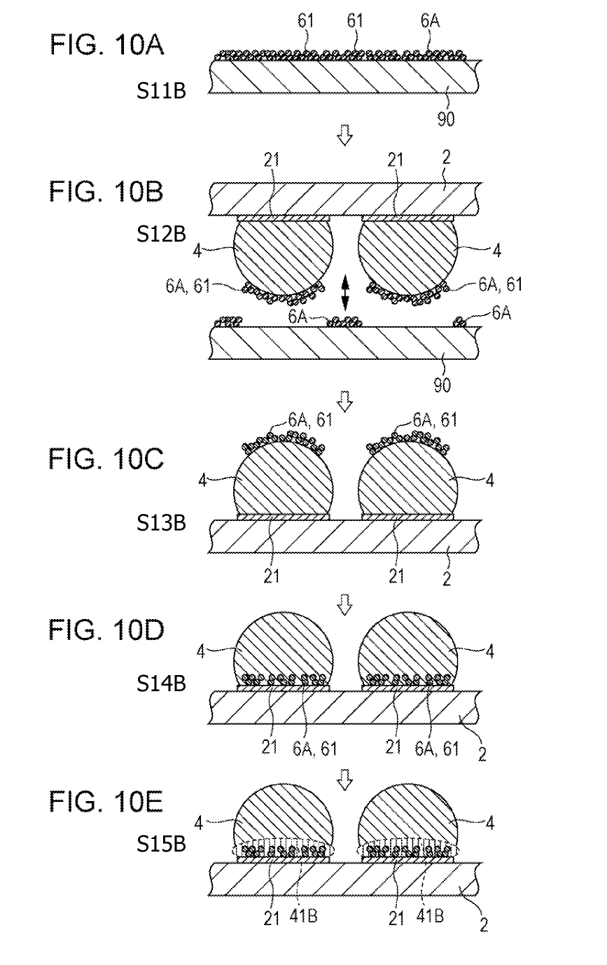

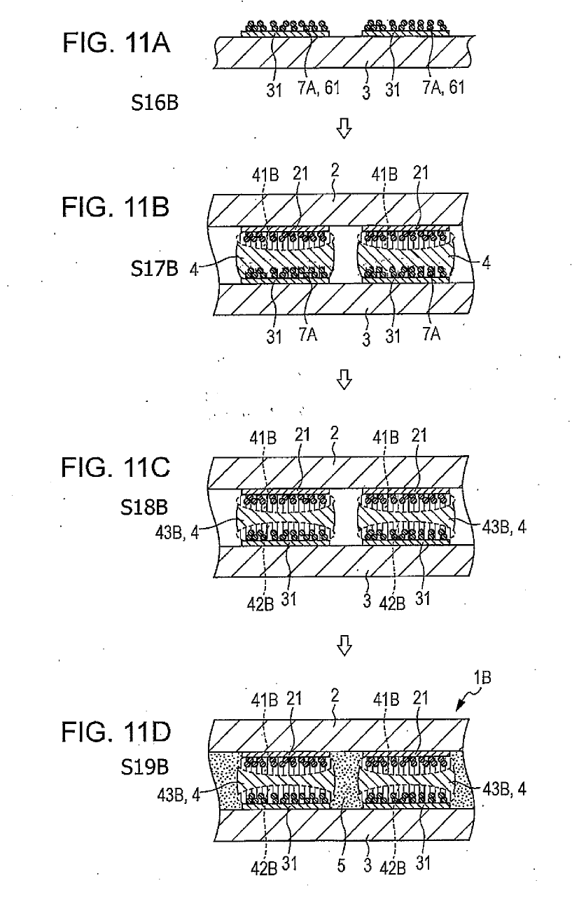

FIGS. 10A to 10E and FIGS. 11A to 11D illustrate an example of the process to manufacture a board module 1B in a third embodiment. The solder ball 4 is made of Sn-3Ag-0.5Bi solder, and solder pastes 6A and 7A are made of Sn—Bi solder including the copper particles 61 by 20 percent by weight.

A manufacturing apparatus (not illustrated) squeezes the solder paste 6A, made of Sn—Bi, that includes the copper particles 61, onto the transfer stage 90 (step S11B). The manufacturing apparatus places the electronic part 2 on which the solder balls 4 made of SAC solder have been mounted on the transfer stage 90 so that the front surface of the electronic part 2 faces down and its rear surface faces up. The manufacturing apparatus then transfers the solder paste 6A from the transfer stage 90 to the surfaces of the solder balls 4 (step S12B). The manufacturing apparatus inverts the electronic part 2 so that the solder paste 6A transferred to the surfaces of the solder balls 4 faces up, that is, the rear surface of the electronic part 2 faces down and its front surface faces up (step S13B). At this time, the solder paste 6A including the copper particles 61 remains applied to the surface of the solder ball 4 mounted on each first electrode 21 on the electronic part 2. Since the specific gravity of the copper particle 61 is 8.92 and that of the solder ball 4 made of SAC solder is 7.047, so the specific gravity of the copper particle 61 is greater than that of the solder ball 4. The diameter of the copper particle 61 is in the range from about 20 μm to about 50 μm, for example. The melting point of the solder ball 4 is about 230° C. and that of the copper particle 61 is about 1,000° C., so the melting point of the copper particle 61 is higher than that of the solder ball 4.

The manufacturing apparatus performs first heat processing on the inverted electronic part 2 to melt the solder balls 4 mounted on the electronic part 2 (step S14B). In the first heat processing, the electronic part 2 is heated for about three minutes at the melting point of the solder ball 4, that is, at a temperature of, for example, about 230° C. As the solder ball 4 melts, the copper particles 61 in the solder paste 6A applied to the surface of the solder ball 4 precipitate under their own weight at the interface between the interior of the melted solder ball 4 and the first electrode 21.

After the copper particles 61 have precipitated at the interface between the interior of the solder ball 4 and the first electrode 21, the manufacturing apparatus performs second heat processing on the electronic part 2 to form a first inter-metal compound layer 41B at the interface between the interior of the solder ball 4 and the first electrode 21 (step S15B). In the second heat processing, the electronic part 2 is heated for about ten hours at a temperature of about 170° C. to form the first inter-metal compound layer 41B, made of Cu—Sn, having a high melting point with the copper particles 61 and tin component.

The manufacturing apparatus applies the solder paste 7A including the copper particles 61 to each second electrode 31 disposed on the front surface of the printed circuit board 3 (step S16B). The solder paste 7A is made of Sn—Bi solder including the copper particles 61. The manufacturing apparatus performs third heat processing on the printed circuit board 3 and electronic part 2 with the solder ball 4 mounted on each first electrode 21 being brought into contact with the solder paste 7A applied to the relevant second electrode 31 (step S17B). In the third heat processing, the electronic part 2 and printed circuit board 3 are heated for about three minutes at the melting point of the solder ball 4, that is, at a temperature of, for example, about 230° C.

After having performed the third heat processing on the electronic part 2 and printed circuit board 3, the manufacturing apparatus performs fourth heat processing on the electronic part 2 and printed circuit board 3 to form a second inter-metal compound layer 42B at an interface between the interior of the solder ball 4 and the second electrode 31 (step S18B). In the fourth heat processing, the electronic part 2 and printed circuit board 3 are heated for about ten hours at a temperature of, for example, about 170° C. to form the second inter-metal compound layer 42B, made of Cu—Sn, having a high melting point with the copper particles 61 and tin component. Furthermore, in the board module 1B, an intermediate layer 43B is formed between the first inter-metal compound layer 41B and the second inter-metal compound layer 42B by using the solder ball 4 disposed between the first inter-metal compound layer 41B and the second inter-metal compound layer 42B.

After having formed the second inter-metal compound layer 42B at the interface between the interior of the solder ball 4 and the second electrode 31, the manufacturing apparatus uses a dispenser (not illustrated) to fill each space between the electronic part 2 and the printed circuit board 3 with the under-fill material 5 (step S19B). This completes the manufacturing of the board module 1B, by the manufacturing apparatus, in which the electronic part 2 and printed circuit board 3 are bonded together.

When the solder balls 8 are mounted on the rear surface of the completed board module 1B or the board module 1B is placed on the mother board 11 as the secondary mounting by using the solder balls 8, each solder ball 4, which bonds the first electrode 21 and second electrode 31 together in the board module 1B, also melts again. Since the first inter-metal compound layer 41B and second inter-metal compound layer 42B (see FIG. 11D) have a high melting point, however, it is possible to suppress solder flashes from being formed near the first electrode 21 and second electrode 31.

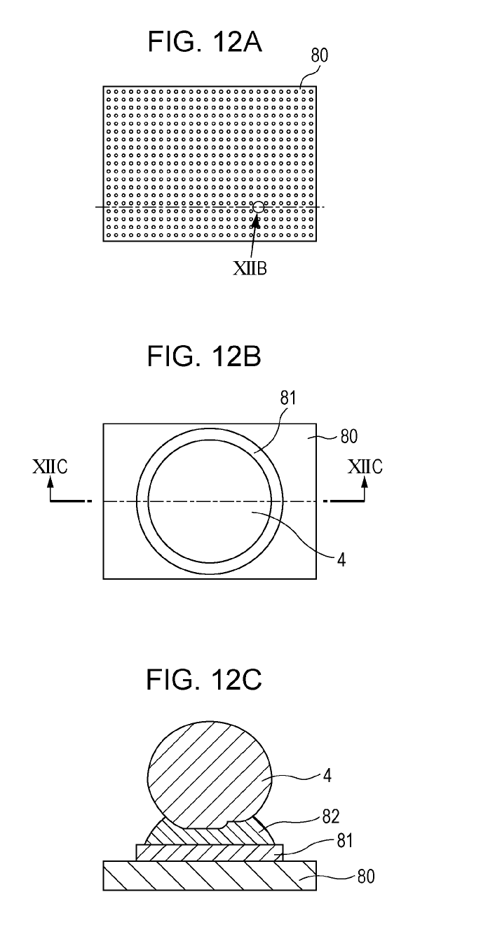

Next, an example of an experiment in which the Sn—Bi solder paste in the third embodiment was used will be described. FIGS. 12A to 12C illustrate an example of an experiment in which the third embodiment was used. FIG. 12B is a plan view of a test element group (TEG) board 80. FIG. 12B is an enlarge plan view of a region including an electrode 81 on the TEG board 80. FIG. 12C is a cross sectional view of the region including the electrode 81. The solder ball 4, made of SAC solder, with a particle diameter of 250 μm was mounted on the electrode 81 placed on the front surface of the TEG board 80 in FIGS. 12A and 12B. Then, Sn—Bi solder paste including copper particles with an average particle diameter of 20 μm by 20 percent by weight was applied to a printing plate (not illustrated). In addition, the solder paste was applied to the surface of each solder ball 4 mounted on the front surface of the TEG board 80.

Reflow processing was performed on the TEG board 80 at a peak temperature of 230° C. to melt the mounted solder balls 4. An epoxy resin was applied to the solder balls 4 on the TEG board 80. The TEG board 80 was further heated for 0.5 hour at a temperature of 125° C. to thermally cure the epoxy resin. The TEG board 80 was then heated for ten hours at a temperature of 170° C. to form an inter-metal compound layer 82 made of Cu—Sn at an interface with each electrode 81 and the relevant solder ball 4. As a result, the inter-metal compound layer 82 made of Cu—Sn was formed at the interface between the electrode 81 and the solder ball 4 on the electrode 81 disposed on the TEG board 80.

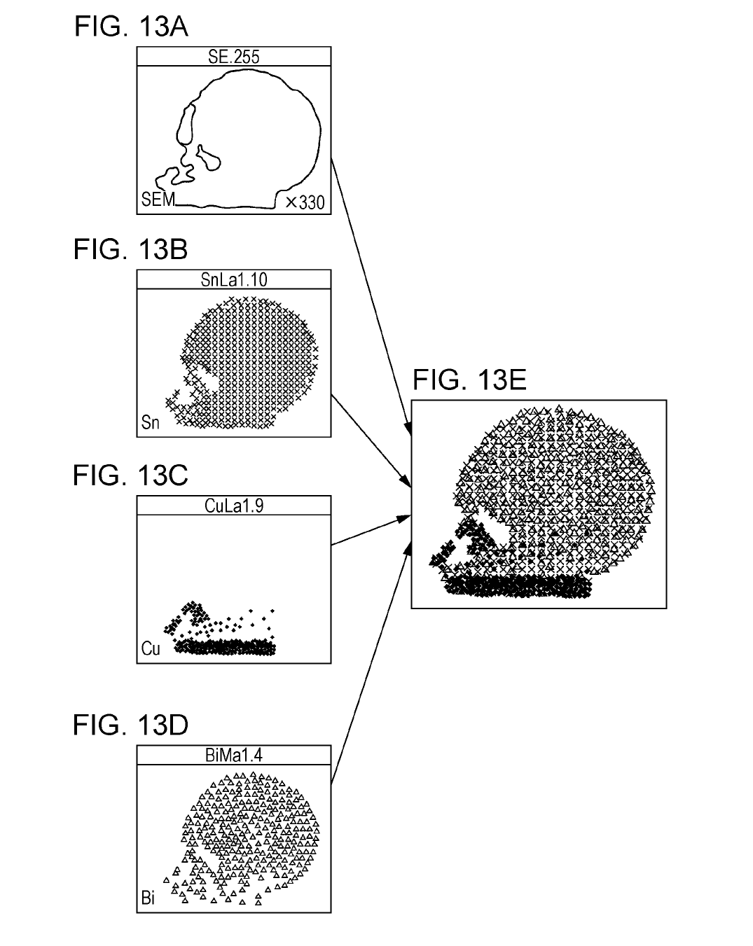

To verify the effect of suppressing solder flashes, the TEG board 80 was left for 24 hours in a hot and humid environment (at a temperature of 85° C. and at a humidity of 85%) and then was heated for five minutes at a temperature of 230° C. by using a heating plate. Analysis results of the metal compositions in the solder ball 4 and inter-metal compound layer 82 on the electrode 81 mounted on the TEG board 80 were verified. FIGS. 13A to 13E illustrate exemplary analysis results.

FIG. 13A illustrates an image of the main part of the solder ball 4 and inter-metal compound layer 82, which was taken by a scanning electron microscope (SEM). FIG. 13B illustrates the tin (Sn) component of the main part, FIG. 13C illustrates the copper (Cu) component of the main part, and FIG. 13D illustrates the bismuth (Bi) component of the main part. FIG. 13E is a combination of FIGS. 13A to 13D.

From verification results in this experiment, it was found with reference to FIGS. 13A to 13E that the inter-metal compound layer 82 made of Cu and Sn—Cu was formed below the SAC solder, which was a component of the solder ball 4, and Sn—Bi, which was a component of the solder paste 7, that is, at the interface with the electrode 81 and the solder ball 4. It was also found that even when the TEG board 80 was heated to the melting point of the solder ball 4 (about 230° C.) by using the heating plate to melt the solder ball 4, the inter-metal compound layer 82 did not melt.

In the manufacturing method in the third embodiment, not only the second inter-metal compound layer 42B is formed on the same side as the second electrode 31, but also the first inter-metal compound layer 41B having a high melting point may be easily formed on the same side as the first electrode 21, on which the solder ball 4 has been mounted in advance.

In addition, the board module 1B includes the first inter-metal compound layer 41B formed at the interface between the interior of the solder ball 4 and the first electrode 21 and also includes the second inter-metal compound layer 42B formed at the interface between the interior of the solder ball 4 and the second electrode 31. When the board module 1B is placed on the mother board 11 as the secondary mounting, each solder ball 4, which bonds the first electrode 21 and second electrode 31 together in the board module 1B, melts again. Even when the solder ball 4 melts again, the first inter-metal compound layer 41B and second inter-metal compound layer 42B do not melt because they have a high melting point, suppressing solder flashes from being formed on the first electrode 21 and second electrode 31.

The board module 1B also includes the intermediate layer 43B, which is formed with the low-melting point component of the solder ball 4, between the first inter-metal compound layer 41B and the second inter-metal compound layer 42B. Accordingly, although the intermediate layer 43B has a lower melting point than the first inter-metal compound layer 41B and second inter-metal compound layer 42B, the intermediate layer 43B is superior in solder wettability, electrical conductivity, and physical strength to solder including a large amount of copper.

In the manufacturing method in the third embodiment, the tin component and the copper particles 61 that precipitated at the interface between the interior of the solder ball 4 and the first electrode 21 have been heated for about ten hours at a temperature of, for example, about 170° C. to form the first inter-metal compound layer 41B, made of Cu—Sn, at the interface between the interior of the solder ball 4 and the first electrode 21. As a result, the first inter-metal compound layer 41B having a higher melting point than the solder ball 4 may be formed at the interface between the interior of the solder ball 4 and the first electrode 21.

Although, in the above embodiments, the solder ball 4 mounted on the first electrode 21 placed on the electronic part 2 has been exemplified as an example of a solder bump, this is not a limitation.

Although, in the above embodiments, the copper particles 61 have been included in the solder paste 6 applied to the surface of the solder ball 4 and in the solder paste 7 applied to the second electrode 31, silver particles or gold particles may be included instead of the copper particles 61. If the solder pastes 6 and 7 including silver particles are used, for example, an Ag—Sn inter-metal compound layer having a higher melting point than the solder ball 4 is formed at the interface between the first electrode 21 and the second electrode 31. If the solder pastes 6 and 7 including gold particles are used, an Au—Sn inter-metal compound layer having a higher melting point than the solder ball 4 is formed at the interface between the first electrode 21 and the second electrode 31. The solder pastes may include at least any one type of the copper particles, silver particles, and gold particles or may include a combination of these types of particles.

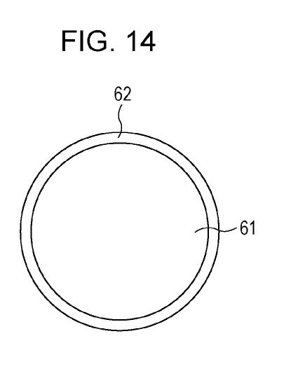

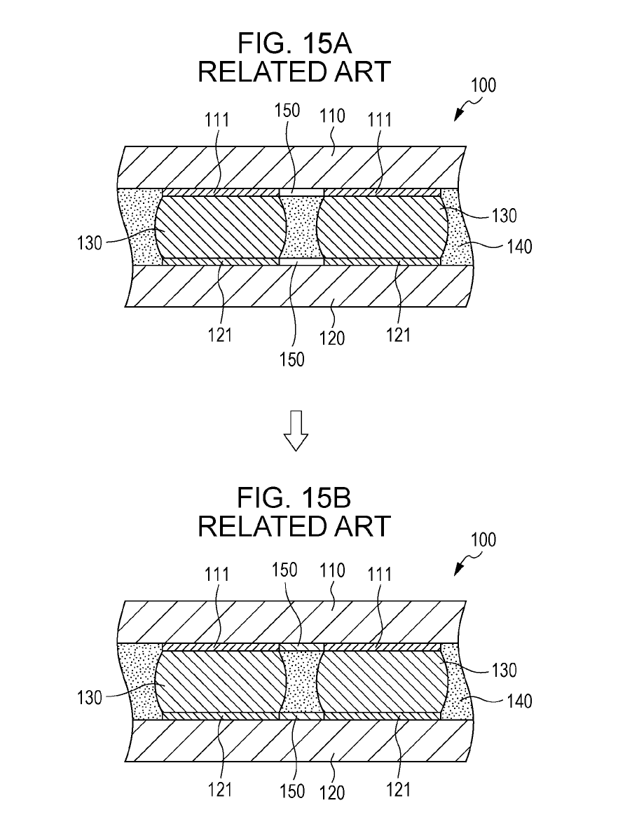

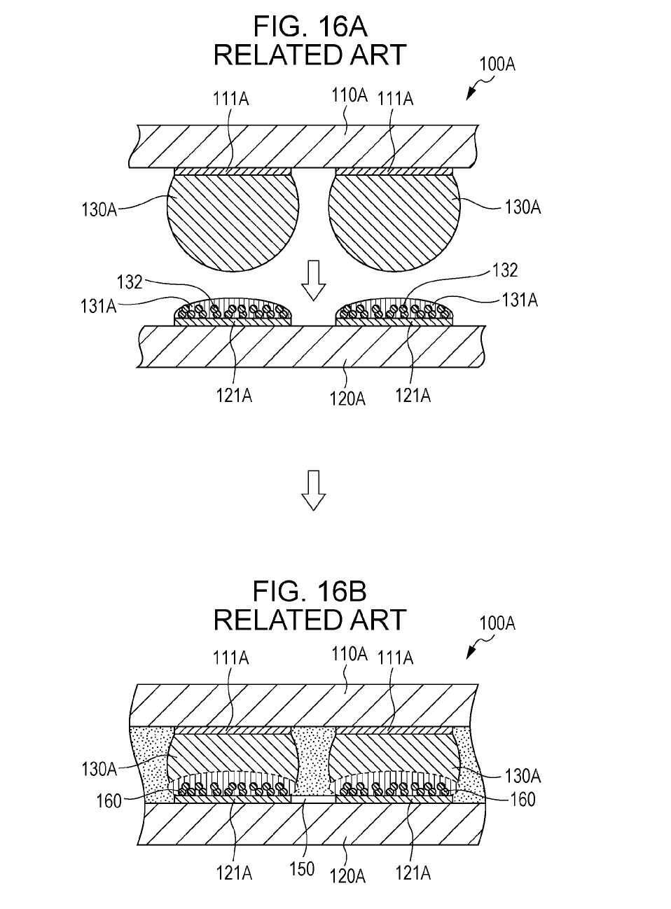

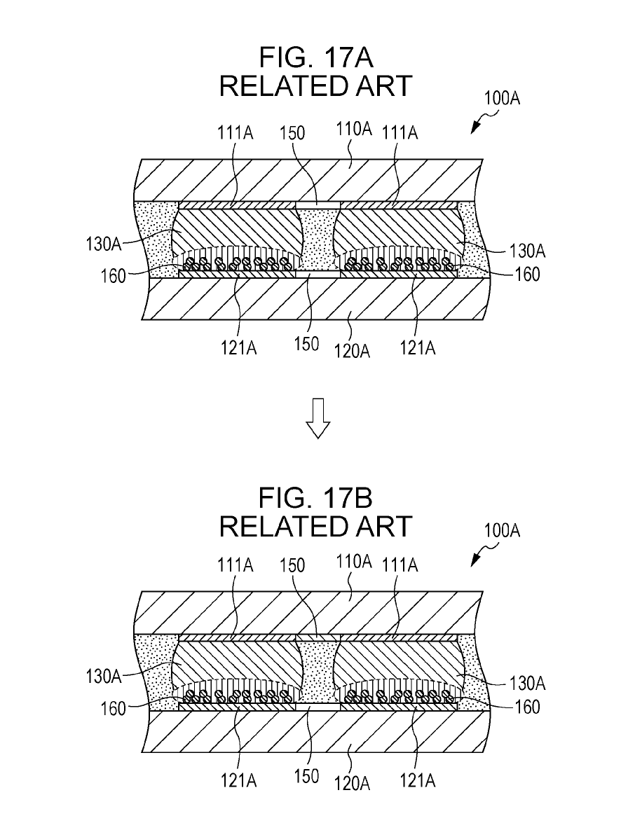

Although, in the above embodiments, the copper particles 61 have been included in the solder paste 6 applied to the surface of the solder ball 4 and in the solder paste 7 applied to the second electrode 31, the copper particles 61 that are silver-plated may be included in the silver pastes 6 and 7. FIG. 14 illustrates an example of a silver-plated copper particle. The copper particle 61 in FIG. 14 has a particle diameter in the range, for example, from about 20 μm to about 49 μm, and a silver plating 62 on the copper particle 61 has a thickness of, for example, 1 μm or less. The silver plating 62 may be formed by electroless plating. The copper particle 61 may be gold-plated, for example, instead of being silver-plated.

In the above embodiments, the electronic part 2 on which the solder balls 4 was mounted in advance has been used. Even when a printed circuit board on which the solder balls 4 are mounted in advance is used instead of the printed circuit board 2, however, similar effects may be obtained.

Although, in the above embodiments, the solder pastes 6 and 7 including the copper particles 61 have been respectively applied to the surface of the solder ball 4 and the second electrodes 31, a flux including the copper particles 61 may be used.

In the above embodiments, it is also possible to form the first inter-metal compound layer 41 and second inter-metal compound layer 42 by using the whole of the solder ball 4, which bonds the first electrode 21 and second electrode 31 together, without leaving the intermediate layer 43 having a low melting point. If the intermediate layer 43 having a low melting point is not left, however, the content of copper particles 61 is increased, increasing the cost. The wettability of solder is also impaired, lowering reliability in electrical connection, physical properties, and strength. In the above embodiments, therefore, the solder ball 4 having a low melting point has been intentionally left, that is, the intermediate layer 43 has been formed to suppress the material cost by reducing the content of the copper particles 61 and to maintain the wettability of solder, reliability in electrical connection, physical properties, and strength.

Although, in the above embodiments, specific numeric values have been exemplified, this is not a limitation.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A method of manufacturing a board module, the method comprising:
attaching a metal particle to a surface of a solder bump, which includes at least a tin component and is mounted on an electrode provided on a first surface of an electric part or a printed circuit board, the metal particle having a higher specific gravity than that of the solder bump and a higher melting point than that of the solder bump;
making the first surface, on which the electrode is provided, face up;
heating the solder bump to a temperature equal to or higher than the melting point of the solder bump to melt the solder bump so that the metal particle precipitates in the solder bump; and
forming an inter-metal compound layer, which has a higher melting point than a melting point of the solder bump, at an interface between the solder bump and the electrode by using the metal particle, which has precipitated, and the tin component of the solder bump.

2. The method of manufacturing a board module according to claim 1, the method further comprising:
electrically bonding the electrode and an opposite electrode, which is disposed on a second surface facing the electrode, together by heating the solder bump to a temperature higher than the melting point of the solder bump to melt the solder bump, with the surface of the solder bump mounted on the first surface being brought into contact with an opposite metal particle attached to the opposite electrode, the opposite metal particle having a higher melting point than the melting point of the solder bump;
forming an opposite inter-metal compound layer, which has a higher melting point than the melting point of the solder bump, at an interface between the solder bump and the opposite electrode by using the opposite metal particle and the tin component of the solder bump; and
filling a space between the first surface and the second surface with a filling material.

3. The method of manufacturing a board module according to claim 2, the method further comprising:
mounting a solder bump on a rear surface of the second surface of the board module, which is formed by filling the space between the first surface and the second surface with the filling material; and
electrically bonding the board module and a circuit wiring board together by heating the solder bump to a temperature higher than the melting point of the solder bump to melt the solder bump, with the solder bump mounted on the rear surface of the second surface being brought into contact with the circuit wiring board.

4. The method of manufacturing a board module according to claim 3, wherein in the forming the opposite inter-metal compound layer, an intermediate layer is formed between the inter-metal compound layer and the opposite inter-metal compound layer by using the solder bump disposed between the inter-metal compound layer formed at the interface between the solder bump and the electrode and the opposite inter-metal compound layer formed at the interface between the solder bump and the opposite electrode.

5. The method of manufacturing a board module according to claim 1, wherein in the forming the inter-metal compound layer at the interface between the solder bump and the electrode, wherein the metal particle the tin component of the solder bump are heated to a certain temperature to form the inter-metal compound layer at the interface between the solder bump and the electrode, the metal particle having precipitated in the solder bump on the same side as the interface between an interior of the solder bump and the electrode.

6. The method of manufacturing a board module according to claim 1, wherein the solder bump is tin-silver-copper solder or tin-bismuth solder.

7. The method of manufacturing a board module according to claim 1, wherein the metal particle includes at least any one of copper, gold, silver, gold-plated copper, and silver-plated copper.

8. The method of manufacturing a board module according to claim 7, wherein the meal particle is included in tin-silver-copper solder, tin- bismuth solder, tin-silver-copper flux paste, or tin- bismuth flux paste.

9. The method of manufacturing a board module according to claim 8, wherein when the metal particle is a copper particle, an amount of copper included in the paste is 10 to 20 percent by weight.

10. The method of manufacturing a board module according to claim 7, wherein the metal particle have an average particle diameter in a range from 20 μm to 50 μm.

11. A board module comprising:
a first surface of an electronic part or a printed circuit board;
a first electrode provided on the first surface;
a solder bump including at least a tin component, the solder bump being mounted on the first electrode;
a first inter-metal compound layer having a higher melting point than a melting point of the solder bump, the first inter-metal compound layer being formed at an interface between an interior of the solder bump and the first electrode by using the tin component of the solder bump and a first metal particle, which has precipitated in the solder bump on the same side as the interface between the solder bump and the first electrode, the first metal particle having a higher specific gravity than a specific gravity of the solder bump and a higher melting point than a melting point of the solder bump;
a second surface opposite to the first surface;
a second electrode provided on the second surface;
a second inter-metal compound layer having a higher melting point than the melting point of the solder bump, the second inter-metal compound layer being formed at an interface between the solder bump and the second electrode by using the tin component of the solder bump mounted on the first electrode and a second metal particle attached to the second electrode, the second metal particle having a higher melting point than the melting point of the solder bump; and
an intermediate layer formed between the first inter-metal compound layer and the second inter-metal compound layer by using the solder bump disposed between the first inter-metal compound layer and the second inter-metal compound layer.

12. The board module according to claim 11, wherein:
the first surface is a surface of the electronic part; and the second surface is a surface of the printed circuit board.

13. A board module assembly comprising:
a board module that include
a first surface of an electronic part or a printed circuit board;
a first electrode provided on the first surface,
a solder bump including at least a tin component, the solder bump being mounted on the first electrode,
a first inter-metal compound layer having a higher melting point than a melting point of the solder bump, the first inter-metal compound layer being formed at an interface between an interior of the solder bump and the first electrode by using the tin component of the solder bump and a first metal particle, which has precipitated in the solder bump on the same side as the interface between the solder bump and the first electrode, the first metal particle having a higher specific gravity and a higher melting point than the melting point of the solder bump,
a second surface opposite to the first surface,
a second electrode provided on the second surface,
a second inter-metal compound layer having a higher melting point than the melting point of the solder bump, the second inter-metal compound layer being formed at an interface between the solder bump and the second electrode by using the tin component of the solder bump mounted on the first electrode and a second metal particle attached to the second electrode, the second metal particle having a higher melting point than the melting point of the solder bump,
an intermediate layer formed between the first inter-metal compound layer and the second inter-metal compound layer by using the solder bump disposed between the first inter-metal compound layer and the second inter-metal compound layer, and
a filling material with which a space between the first surface and the second surface is filled; and
a circuit wiring board bonded to the second surface with a solder bump mounted on a rear surface of the second surface of the board module.
